(19) United States
(12) Patent Application Publication
(10) Pub. No.: US 2006/0261458 A1
(43) Pub. Date: Nov. 23, 2006

(54) Semiconductor package and manufacturing method thereof

(75) Inventors: Jong Sik Paek, Gyeonggi-do (KR); Jin Seong Kim, Gyeonggi-do (KR); Seong Min Seo, Seoul (KR)

Correspondence Address: Serge J. Hodgson;Gunnison, McKay & Hodgson, L.L.P., Suite 220, 1900 Garden Road, Monterey, CA, 93940, US

(73) Assignee: Amkor Technology, Inc.

(21) Appl. No.: 10/712,839

(22) Filed: Nov. 12, 2003

(51) Int. Cl. H01L 23/02

(52) U.S. Cl. 257/680

(57) ABSTRACT

A semiconductor package and manufacturing method thereof are disclosed. The semiconductor package includes a substrate having an image sensor die, window, a glass, and solder balls. Not only the substrate having the window is attached to the upper side of the image sensor die, but also one side of the substrate extends and is bent so that the one side of the substrate is attached to the lower side of the image sensor die, thereby reducing the thickness and width of the semiconductor package. In another embodiment, at least one memory die can be stacked in an image sensor die or a substrate, so that the functions of the semiconductor package is growing multifarious and the package efficiency is increased.

### BACKGROUND OF THE INVENTION

1. Field of the Invention

The field of the present invention is related to semiconductor packages and manufacturing methods thereof.

2. Description of the Related Art

In general, image sensor dies have a wide range of uses, including toys, digital cameras, camcorders, scanners, medical scopes, watch cameras, and cell phones, and mainly plays a role of processing dynamic images or still images. Recently, as image sensor dies are provided at cameras and cell phones, etc., demand for image sensor dies has explosively increased. Further, it is expected that image sensor dies will emerge as the next generation semiconductor gpld market.

A conventional semiconductor package, at which the image sensor die is provided, has a substrate in which the image sensor die is installed, conductive wires for electrically connecting the image sensor die to the substrate, a glass for transmitting outside light to the image sensor die side, and a mount for fixing the glass to the substrate.

Accordingly, the conventional semiconductor package needs not only more glass but also a mount having a complex structure in comparison to a general semiconductor package, thereby not only complicating the entire structure of the semiconductor package but also increasing the manufacturing cost.

Further, since the mount for fixing the glass must have such a thickness as to cover a wire loop height, the entire thickness of the semiconductor package grows thicker.

In addition, the mount for fixing the glass and the wire loop height make it difficult to realize a semiconductor package having a CSP type close to a die size.

Furthermore, since other dies, such as a memory device die, cannot be stacked in addition to the image sensor die, the conventional semiconductor package cannot meet the requirements of multi-functionalization of semiconductor packages.

### BRIEF SUMMARY OF THE INVENTION

In one embodiment, a semiconductor package includes a substrate having an image sensor die, a window, a glass, and solder balls. Not only the substrate having the window is attached to upper side of the image sensor die, but also one side of the substrate extends and is bent so that the one side of the substrate is attached to a lower side of the image sensor die, thereby reducing the thickness and width of the semiconductor package. In another embodiment, at least one memory die can be stacked in an image sensor die or a substrate, so that the functions of the semiconductor package is growing multifarious and the package efficiency is increased.

The present invention is best understood by reference to the following detailed description when read in conjunction with the accompanying drawings.

### BRIEF DESCRIPTION OF THE DRAWINGS

FIG. 1 is a cross-sectional view of a semiconductor package according to one embodiment of the present invention;

FIG. 2 is a cross-sectional view of a semiconductor package according to another embodiment of the present invention;

FIG. 3 is a cross-sectional view of a semiconductor package according to another embodiment of the present invention;

FIG. 4 is a cross-sectional view of a semiconductor package according to another embodiment of the present invention;

FIG. 5 is a cross-sectional view of a semiconductor package according to another embodiment of the present invention;

FIG. 6 is a cross-sectional view of a semiconductor package according to another embodiment of the present invention;

FIG. 7 is a cross-sectional view of a semiconductor package according to another embodiment of the present invention; and

FIGS. 8a to 8g are views illustrating a manufacturing method of a semiconductor package according to the present invention.

Common reference numerals are used throughout the drawings and detailed description to indicate like elements.

### DETAILED DESCRIPTION

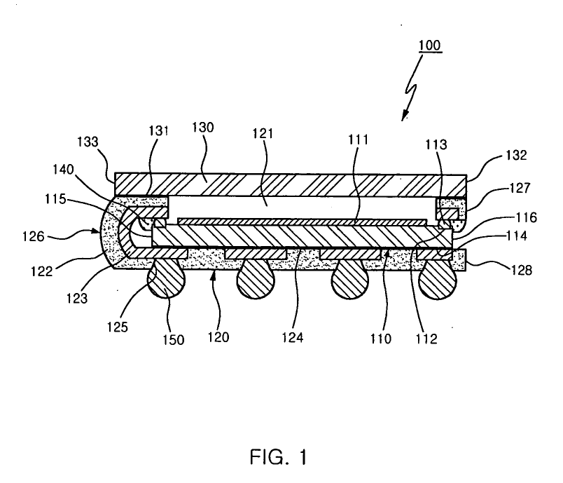

Referring to FIG. 1, a cross-sectional view of a semiconductor package 100 according to one embodiment of the present invention is illustrated.

As shown, the semiconductor package 100 according to the present invention includes an image sensor die 110, a substrate 120, a glass 130, a plurality of solder balls 150. The image sensor die 110 receives outside lights (images) and converts the lights into electrical signals. The substrate 120 intermediates electrical signals between the image sensor die 110 and an outside apparatus (not shown). The glass 130 enables lights (images) to be incident into the image sensor die 110 and protects the image sensor die 110 from the outside environment. The plurality of solder balls 150 are attached to the substrate 120 and mounted on an outside apparatus.

First, the image sensor die 110 has an approximately planar or planar photo sensing surface 111 on its upper side so that lights incident from an outside can be converted into electrical signals. The photo sensing surface 111 has a plurality of bond pads 112, to which conductive bumps 113 are attached, around the photo sensing surface 111. These conductive bumps 113, sometimes called first conductive bumps, may be made from gold (Au), silver (Ag), solder (Sn/Pb), or their equivalents. The scope of the present invention is not limited to the above materials.

Further, the image sensor die 110 has an approximately planar or planar non-photo sensing surface 114 on its lower side, which is opposite to the photo sensing surface 111. Side surfaces 115 and 116, each of which is approximately perpendicular to both photo sensing surface 111 and the non-photo sensing surface 114, are formed between the photo sensing surface 111 and the non-photo sensing surface 114. The image sensor die 110 may be either an image sensor having a CMOS type or an image sensor having a CCD type. Herein, the scope of the present invention is not limited to particular kinds of image sensors.

Next, the substrate 120 includes an insulative layer 122 having a window 121 with a predetermined size, which is formed at an area corresponding to the photo sensing surface 111 of the image sensor die 110. This insulative layer 122 may be made from flexible film, flexible tape, or their equivalents. Herein, the scope of the present invention is not limited to above materials.

The insulative layer 122 is flexible, and therefore the insulative layer 122 passes one side of the window 121, that is, one side surface 115 of the image sensor die 110 in a curved shape, and extends over the entire non-photo sensing surface 114.

Further, the insulative layer 122 has a plurality of electrically conductive patterns 123 attached to areas corresponding to the conductive bumps 113. The electrically conductive patterns 123 also pass one side surface 115 of the image sensor die 110, and extend over the entire non-photo sensing surface 114 in a curved shape. In addition, the conductive bumps 113 of the image sensor die 110 are electrically connected to the electrically conductive patterns 123 formed around the window 121.

The non-photo sensing surface 114 of the image sensor die 110 is attached to the insulative layer 122 and the electrically conductive patterns 123 by an adhesive 124, sometimes called a first adhesive. In addition, a plurality of holes 125, sometimes called first holes, are formed at the insulative layer 122 corresponding to the non-photo sensing surface 114 of the image sensor die 110 so that the electrically conductive patterns 123 are opened downward.

Also, the substrate 120 with this structure has a curved portion 126, sometimes called a first curved portion, with a curvature formed in an area corresponding to one side surface 115 of the image sensor die 110. Herein, when the substrate 120 is bent from one side surface 115 of the image sensor die 110 at a right angle to extend over the entire non-photo sensing surface 114, the electrically conductive patterns 123 may be broken. Therefore, the insulative layer 122 and the electrically conductive patterns 123 are bent with a curvature to prevent the electrically conductive patterns 123 from being broken. As a result, the curved portion 126 protrudes outward from one side surface 115 of the image sensor die 110 by a length.

Further, a side surface 127 of the substrate 120 is level with a side surface 128 of the substrate 120. That is, the side surface 127 formed at an upper side of the photo sensing surface 111 of the image sensor die 110 is level with the side surface 128 formed at a lower side of the non-photo sensing surface 114 of the image sensor die 110. Furthermore, the side surfaces 127 and 128 of the substrate 120 protrude slightly farther than the side surface 116 of the image sensor die 110. Herein, the protruding portion has a length of below 10% of an entire size of the image sensor die 110, and therefore the size of the semiconductor package is nearly equal to that of the image sensor die 110.

Also, an encapsulant 140 is doped around the conductive bumps 113. That is, the encapsulant 140 is doped between the image sensor die 110 and substrate 120 surrounding the window 121, thereby preventing outside impurities from permeating into an inside of the window 121 and the photo sensing surface 111. It is suitable that the encapsulant 140 is also doped so as not to exceed one side surface 127 of the substrate 120. This encapsulant 140 may be made from under fill, glob top, coating material, or their equivalents. The scope of the present invention is not limited to above materials.

Next, an adhesive 131, sometimes called a second adhesive, is interposed between the glass 130 and circumference of the window 121 in the substrate 120, and the glass 130 is attached to the substrate 120 by the adhesive 131. This glass 130 has side surfaces 132 and 133, and one side surface 132 is approximately level with the side surfaces 127 and 128 of the substrate 120. Further, the curved portion 126 of the substrate 120 further protrudes outward than the other side surface 133 of the glass 130.

This glass 130 enables outside lights to be incident into the photo sensing surface 111 of the image sensor die 110 and simultaneously prevents outside impurities from permeating into an inside of the window 121 and the photo sensing surface 111. Further, a glass capable of cutting infrared-rays may be used as the glass 130, so as to prevent unnecessary noise signals from being inputted to the photo sensing surface 111 of the image sensor die 110.

Lastly, each of the solder balls 150 is located at each of the holes 125 in the substrate 120, so that the solder balls 150 are electrically connected to the electrically conductive patterns 123. Therefore, electrical signals of the image sensor die 110 are sent to outside apparatuses through the bond pads 112, the conductive bumps 113, the electrically conductive patterns 123 and the solder balls 150 of the substrate 120, and vice versa.

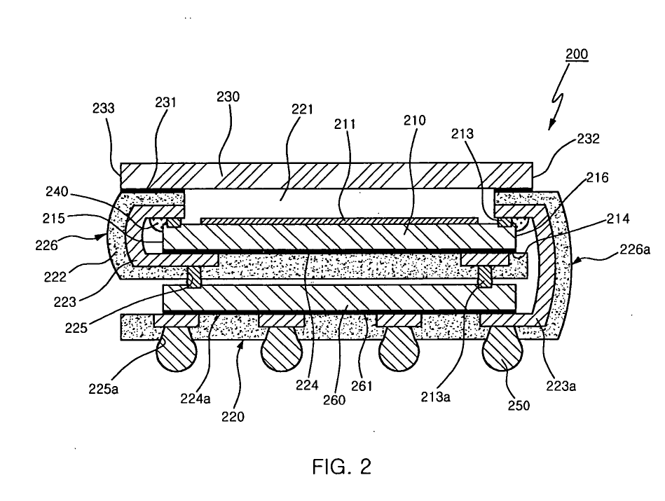

Referring to FIG. 2, a cross-sectional view of a semiconductor package 200 according to another embodiment of the present invention is illustrated.

Since the semiconductor package 200 shown in FIG. 2 is approximately similar to the semiconductor package 100 shown in FIG. 1, the semiconductor package 200 will be described while putting emphasis on a difference between the semiconductor package 100 and the semiconductor package 200. The photo sensing surface 211, conductive bumps 213, non-photo sensing surface 214, side surface 215, insulative layer 222, electrically conductive patterns 223, adhesive 224, curved portion 226, glass 230, adhesive 231, side surfaces 232, 233 and encapsulant 240 of semiconductor package 200 of FIG. 2 are similar to the photo sensing surface 111, conductive bumps 113, non-photo sensing surface 114, side surface 115, insulative layer 122, electrically conductive patterns 123, adhesive 124, curved portion 126, glass 130, adhesive 131, side surfaces 132, 133 and encapsulant 140, respectively, of semiconductor package 100 of FIG. 1, the discussion of which is incorporated herein.

As shown, in the semiconductor package 200 according to another embodiment of the present invention, conductive bumps 213a, sometimes called second conductive bumps, are inserted into holes 225 of a substrate 220 so that they are connected to bond pads of a first memory die 260. The substrate 220 in circumference of a window 221 extends outward while surrounding a side surface 216 of an image sensor die 210 and it is simultaneously bent so that it extends over a lower surface 261 of the first memory die 260. Herein, the first memory die 260 is attached to the substrate 220 located under the first memory die 260 by an adhesive 224a, sometimes called a second or third adhesive.

Further, the substrate 220 located under the first memory die 260 has holes 225a, sometimes called second holes, so that a plurality of electrically conductive patterns 223a may be exposed outward. Herein, solder balls 250 are attached to the holes 225a. The substrate 220 has a curved portion 226a, sometimes called a second curved portion, formed at the side surface 216 of the image sensor die 210 so as to prevent the electrically conductive patterns 223a from being broken. In this way, the first memory die 260 can be further mounted on the semiconductor package 200 in addition the image sensor die 210 according to the present invention, thereby not only contributing multi-functionalization of the semiconductor package 200, but also improving the package efficiency.

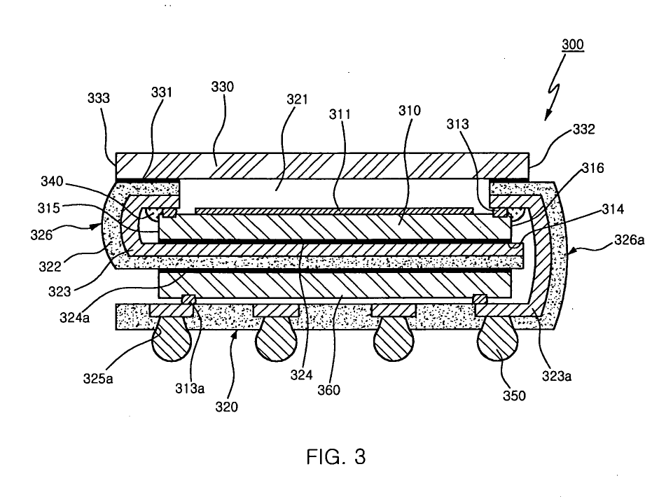

Referring to FIG. 3, a cross-sectional view of a semiconductor package 300 according to another embodiment of the present invention is illustrated.

Since the semiconductor package 300 shown in FIG. 3 is approximately similar to the semiconductor package 200 shown in FIG. 2, the semiconductor package 300 will be described while putting emphasis on a difference between the semiconductor package 200 and the semiconductor package 300. The photo sensing surface 311, conductive bumps 313, side surfaces 315, 316, window 321, insulative layer 322, electrically conductive patterns 323, adhesive 324, holes 325a, curved portions 326, 326a, glass 330, adhesive 331, side surfaces 332, 333, encapsulant 340, and solder balls 350 of semiconductor package 300 of FIG. 3 are similar to the photo sensing surface 211, conductive bumps 213, side surfaces 215, 216, window 221, insulative layer 222, electrically conductive patterns 223, adhesive 224, holes 225a, curved portions 226, 226a, glass 230, adhesive 231, side surfaces 232, 233, encapsulant 240, and solder balls 250, respectively, of semiconductor package 200 of FIG. 2, the discussion of which is incorporated herein.

As shown, a lower surface of the substrate 320, which is attached to a non-photo sensing surface 314 of an image sensor die 310, is attached to a first memory die 360 by an adhesive 324a, sometimes called a second or third adhesive. Further, conductive bumps 313a, sometimes called second conductive bumps, are interposed between bond pads of the first memory die 360 and electrically conductive patterns 323a formed in the substrate 320 located under the first memory die 360, so that the first memory die 360 is electrically connected to the electrically conductive patterns 323a.

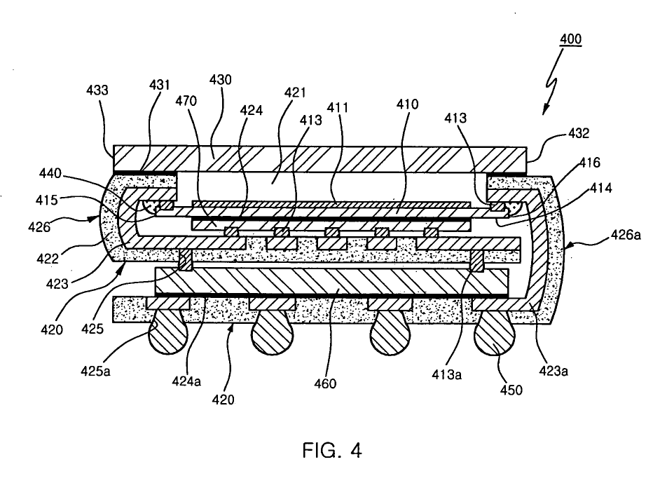

Referring to FIG. 4, a cross-sectional view of a semiconductor package 400 according to another embodiment of the present invention is illustrated.

Since the semiconductor package 400 shown in FIG. 4 is approximately similar to the semiconductor package 200 shown in FIG. 2, the semiconductor package 400 will be described while putting emphasis on a difference between the semiconductor package 200 and the semiconductor package 400. The photo sensing surface 411, conductive bumps 413, 413a, side surfaces 415, 416, window 421, insulative layer 422, electrically conductive patterns 423a, adhesive 424a, holes 425, 425a, curved portions 426, 426a, glass 430, adhesive 431, side surfaces 432, 433, encapsulant 440, and solder balls 450 of semiconductor package 400 of FIG. 4 are similar to the photo sensing surface 211, conductive bumps 213, 213a, side surfaces 215, 216, window 221, insulative layer 222, electrically conductive patterns 223a, adhesive 224a, holes 225, 225a, curved portions 226, 226a, glass 230, adhesive 231, side surfaces 232, 233, encapsulant 240, and solder balls 250, respectively, of semiconductor package 200 of FIG. 2, the discussion of which is incorporated herein.

As shown, another second memory die 470 is located between an image sensor die 410 and a substrate 420 located under the image sensor die 410. An adhesive 424 is interposed between the second memory die 470 and a non-photo sensing surface 414 of the image sensor die 410, so that the second memory die 470 is attached to the non-photo sensing surface 414 by the adhesive 424. Further, conductive bumps 413, sometimes called second or third conductive bumps, are interposed between the bond pads of the second memory die 470 and electrically conductive patterns 423 formed at the substrate 420 located under the second memory die 470, so that the second memory die 470 is electrically connected to the electrically conductive patterns 423. In this way, since not only a first memory die 460 but also the second memory die 470 can be stacked, the functions of the semiconductor package 400 is growing more multifarious.

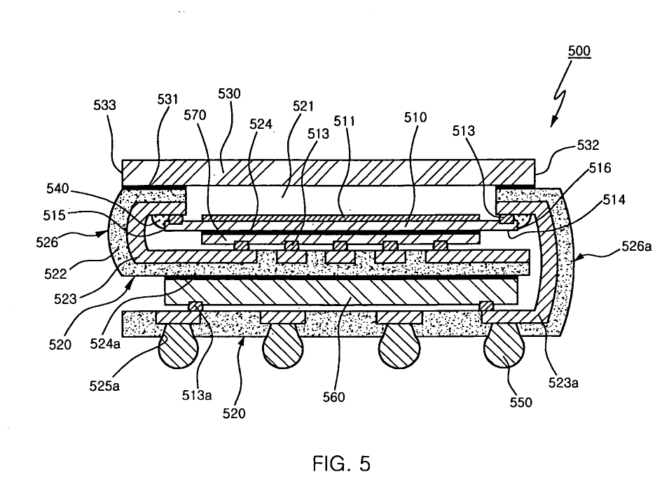

Referring to FIG. 5, a cross-sectional view of a semiconductor package 500 according to another embodiment of the present invention is illustrated.

Since the semiconductor package 500 shown in FIG. 5 is approximately similar to the semiconductor package 400 shown in FIG. 4, the semiconductor package 500 will be described while putting emphasis on a difference between the semiconductor package 400 and the semiconductor package 500. The image sensor die 510, photo sensing surface 511, conductive bumps 513, non-photo sensing surface 514, side surfaces 515, 516, window 521, insulative layer 522, electrically conductive patterns 523, 523a, adhesive 524, curved portions 526, 526a, glass 530, adhesive 531, side surfaces 532, 533, encapsulant 540, and solder balls 550 of semiconductor package 500 of FIG. 5 are similar to the image sensor die 410, photo sensing surface 411, conductive bumps 413, non-photo sensing surface 414, side surfaces 415, 416, window 421, insulative layer 422, electrically conductive patterns 423, 423a, adhesive 424, curved portions 426, 426a, glass 430, adhesive 431, side surfaces 432, 433, encapsulant 440, and solder balls 450, respectively, of semiconductor package 400 of FIG. 4, the discussion of which is incorporated herein.

As shown, an adhesive 524a is interposed between the first memory die 560 and a substrate 520 located at upside of the first memory die 560, so that the first memory die 560 is attached to the substrate 520 by the adhesive 524a. Further, conductive bumps 513a are interposed between the first memory die 560 and the substrate 520 located under the first memory die 560, so that the first memory die 560 is electrically connected to the substrate 520. In this way, since not only the first memory die 560 but also a second memory die 570 can be further stacked in the semiconductor package 500, the semiconductor package 500 may have more functions.

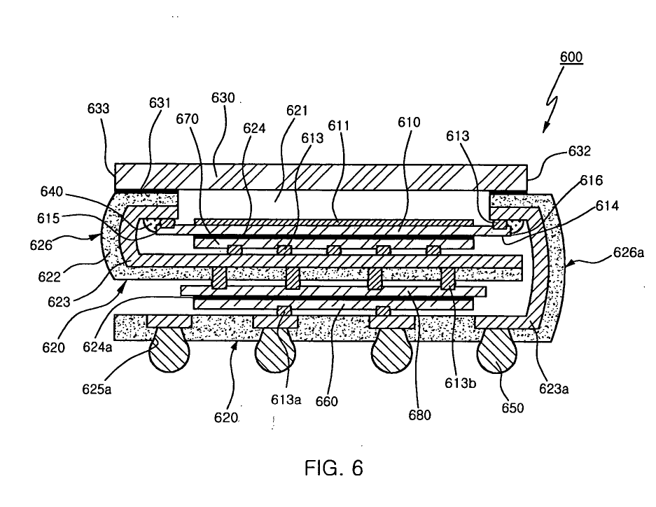

Referring to FIG. 6, a cross-sectional view of a semiconductor package 600 according to another embodiment of the present invention is illustrated.

Since the semiconductor package 600 shown in FIG. 6 is approximately similar to the semiconductor package 500 shown in FIG. 5, the semiconductor package 600 will be described while putting emphasis on a difference between the semiconductor package 500 and the semiconductor package 600. The image sensor die 610, photo sensing surface 611, conductive bumps 613, 613a, non-photo sensing surface 614, side surfaces 615, 616, window 621, insulative layer 622, electrically conductive patterns 623a, adhesive 624, holes 625a, curved portions 626, 626a, glass 630, adhesive 631, side surfaces 632, 633 encapsulant 640, and solder balls 650 of semiconductor package 600 of FIG. 6 are similar to the image sensor die 510, photo sensing surface 511, conductive bumps 513, 513a, non-photo sensing surface 514, side surfaces 515, 516, window 521, insulative layer 522, electrically conductive patterns 523a, adhesive 524, holes 525a, curved portions 526, 526a, glass 530, adhesive 531, side surfaces 532, 533 encapsulant 540, and solder balls 550, respectively, of semiconductor package 500 of FIG. 5, the discussion of which is incorporated herein.

As shown, a third memory die 680 is further located between a first memory die 660 and a substrate 620. That is, conductive bumps 613b are interposed between the third memory die 680 and electrically conductive patterns 623 of the substrate 620, so that the third memory die 680 is electrically connected to the electrically conductive patterns 623. An adhesive 624a is interposed between the third memory die 680 and the first memory die 660, so that the third memory die 680 is attached to the first memory die 660 by the adhesive 624a. In this way, since the first memory die 660, a second memory die 670 and the third memory die 680 can be further stacked in the semiconductor package 600, the semiconductor package 600 may have more functions.

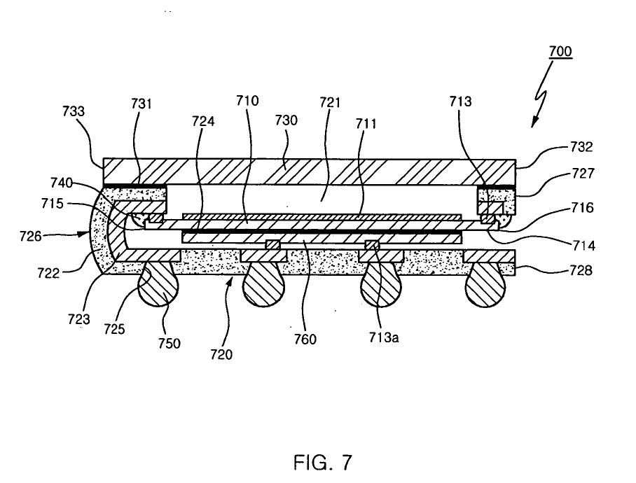

Referring to FIG. 7, a cross-sectional view of a semiconductor package 700 according to another embodiment of the present invention is illustrated.

Since the semiconductor package 700 shown in FIG. 7 is approximately similar to the semiconductor package 100 shown in FIG. 1, the semiconductor package 700 will be described while putting emphasis on a difference between the semiconductor package 100 and the semiconductor package 700. The photo sensing surface 711, conductive bumps 713, side surfaces 715, 716, window 721, insulative layer 722, holes 725, curved portion 726, side surfaces 727, 728, glass 730, adhesive 731, side surfaces 732, 733, encapsulant 740, and solder balls 750 of semiconductor package 700 of FIG. 7 are similar to the photo sensing surface 111, conductive bumps 113, side surfaces 115, 116, window 121, insulative layer 122, holes 125, curved portion 126, side surfaces 127, 128, glass 130, adhesive 131, side surfaces 132, 133, encapsulant 140, and solder balls 150, respectively, of semiconductor package 100 of FIG. 1, the discussion of which is incorporated herein.

As shown, a first memory die 760 is located between an image sensor die 710 and a substrate 720 located under the image sensor die 710. Further, an adhesive 724 is interposed between the first memory die 760 and a non-photo sensing surface 714 of the image sensor die 710, so that the first memory die 760 is attached to the non-photo sensing surface 714 by the adhesive 724. Further, a plurality of conductive bumps 713a are interposed between the first memory die 760 and electrically conductive patterns 723 of the substrate 720, so that the first memory die 760 is electrically connected to the electrically conductive patterns 723. In this semiconductor package 700, the non-photo sensing surface 714 of the image sensor die 710 can be subjected to back-grinding so that the thickness of the non-photo sensing surface 714 can be reduced. Therefore, in accordance with the present invention, a semiconductor package 700 can be realized which not only has multi-functions but also can maintain a very small thickness while containing the first memory die 760.

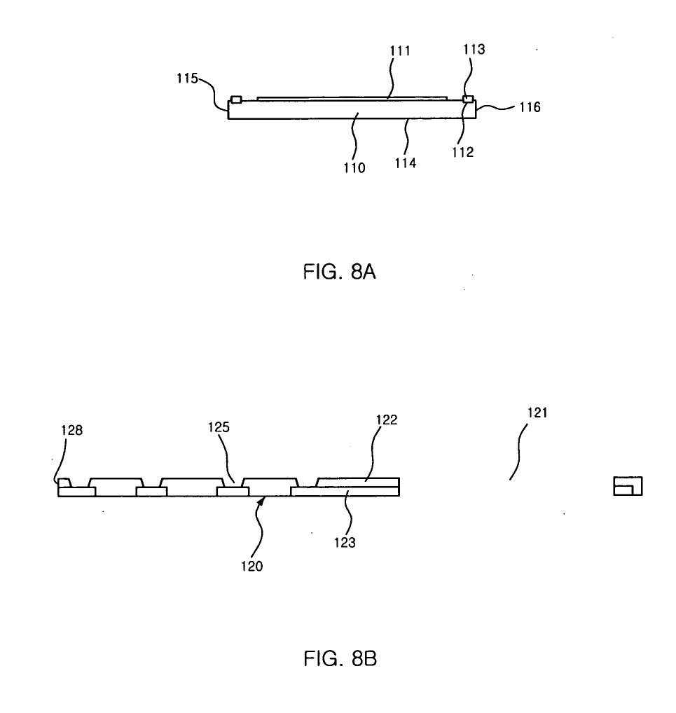

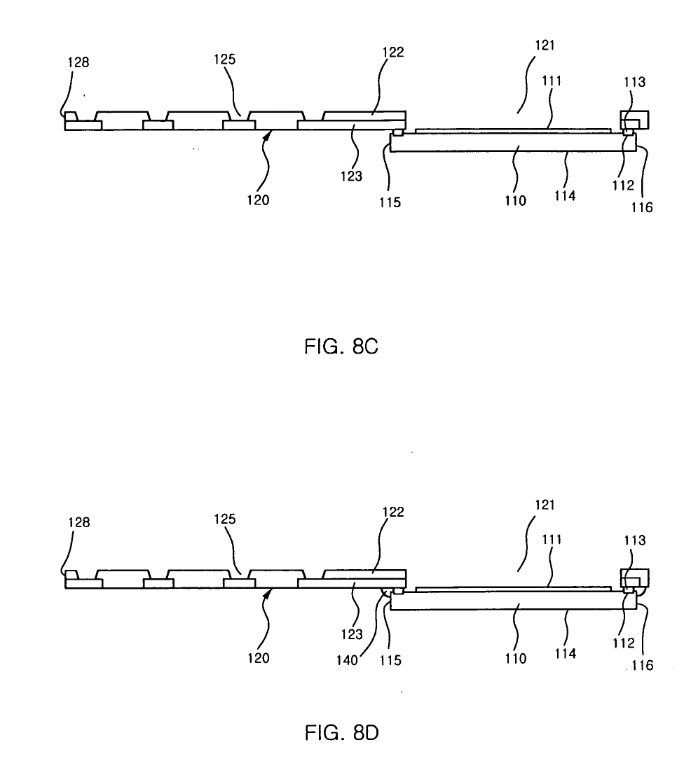

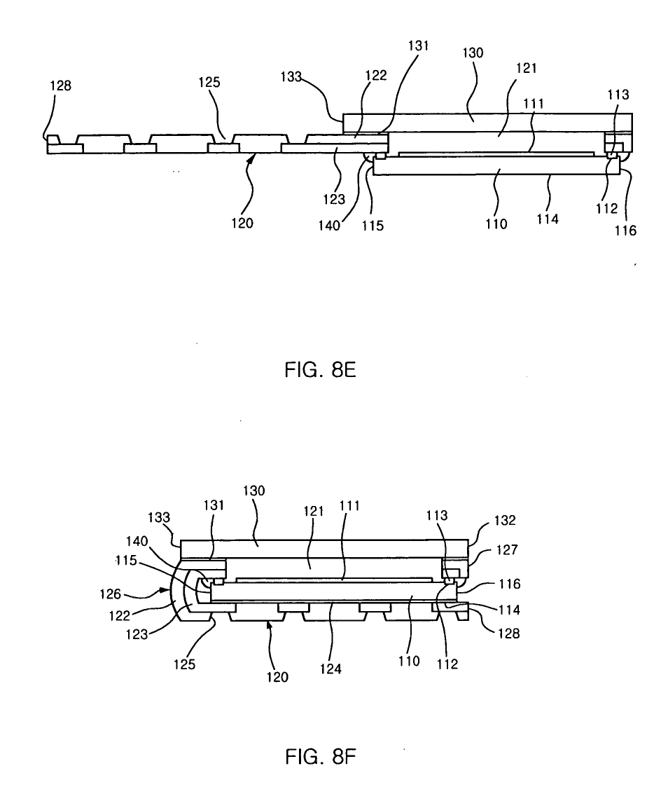

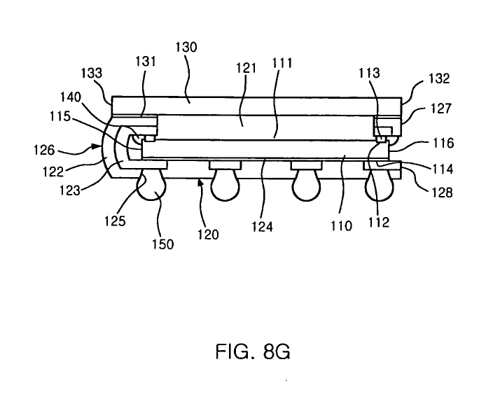

Referring to FIGS. 8A to 8G, a manufacturing method of a semiconductor package according to the present invention are sequentially illustrated.

As shown, a method of manufacturing a semiconductor package according to the present invention includes: 1) providing the image sensor die 110 for receiving outside lights after the photo sensing surface 111 is formed and converting the lights into electrical signals; 2) providing the flexible substrate 120 at which the window 121 is formed so that outside lights can be incident into the photo sensing surface 111; 3) electrically connecting the image sensor die 110 to the substrate 120; 4) doping the encapsulant 140 between the image sensor die 110 and the substrate 120; 5) interposing the adhesive 131 surrounding the window 121 and between the substrate 120 and the glass 130 and attaching the glass 130 above the window 121; 6) bending the substrate 120 so as to cause the substrate 120 to pass one side surface 115 of the image sensor die 110 and extend over the entire non-photo sensing surface 114; and 7) attaching solder balls 150 to the substrate 120 so that the semiconductor package can be mounted on an outside apparatus.

First, FIG. 8A shows the aforementioned operation 1. In operation 1, the image sensor die 110 has an approximately planar or planar photo sensing surface 111 formed at its upper side so that lights incident from an outside can be converted into electrical signals. The plurality of bond pads 112 are formed around the photo sensing surface 111, and the conductive bumps 113 are attached to the bond pads 112. This conductive bump 113 may be made from gold (Au), silver (Ag), solder (Sn/Pb), or their equivalents. Herein, the scope of the present invention is not limited to above materials. Further, the image sensor die 110 has an approximately planar or planar non-photo sensing surface 114 on its lower side, which is opposite to the photo sensing surface 111. Further, the side surfaces 115 and 116, each of which is approximately perpendicular to both the photo sensing surface 111 and the non-photo sensing surface 114, are formed between the photo sensing surface 111 and the non-photo sensing surface 114. This image sensor die 110 may be a general image sensor of a CMOS type or image sensor of a CCD type. Herein, the scope of the present invention is not limited to particular kinds of image sensors.

Next, FIG. 8B shows the aforementioned operation 2. In operation 2, the substrate 120 includes the flexible insulative layer 122 having the window 121, sometimes called an opening, hole, or aperture, with a predetermined size, which is formed at an area corresponding to the photo sensing surface 111 of the image sensor die 110. The insulative layer 122 passes one side of the window 121, that is, one side surface 115 of the image sensor die 110, and extends over circumference of the image sensor die 110 by a predetermined length. It is suitable that the extending length is equal to or slightly larger than the length obtained by adding one side surface 115 of the image sensor die 110 to the non-photo sensing surface 114 of the image sensor die 110. Further, the substrate 120 has a plurality of electrically conductive patterns 123 formed at areas corresponding to the conductive bumps 113 of the image sensor die 110. The electrically conductive patterns 123 also pass one side surface 115 of the image sensor die 110, and extend nearly to the side surface 128 of the insulative layer 122. In addition, the substrate 120 has a plurality of holes 125 formed at its upper surface, so that the electrically conductive patterns 123 can be exposed to an outside through the holes 125.

Next, FIG. 8C shows the aforementioned operation 3. In operation 3, each of the conductive bumps 113 formed at each of the bond pads 112 of the image sensor die 110 is aligned to each of the electrically conductive patterns 123 formed around the window 121 of the substrate 120, and then each conductive bump 113 and each electrically conductive pattern 123 are reflowed, so that the image sensor die 110 is electrically fixed to the substrate 120. Herein, the photo sensing surface 111 of the image sensor die 110 becomes an area corresponding to the window 121 of the substrate 120.

Next, FIG. 8D shows the aforementioned operation 4. In operation 4, the encapsulant 140 is doped around the conductive bumps 113. That is, the encapsulant 140 is doped between the image sensor die 110 and substrate 120 surrounding the window 121, so as to prevent outside impurities from permeating into an inside of the window 121 through gaps between the conductive bumps 113. The encapsulant 140 may be made from under fill, glob top, coating material, or their equivalents. The scope of the present invention is not limited to above materials.

Next, FIG. 8E shows the aforementioned operation 5. In operation 5, the adhesive 131 is interposed between the glass 130 and the substrate 120 surrounding the window 121, so that the glass 130 is attached to the substrate 120 by the adhesive 131. This glass 130 has a shape similar to a plate and two side surfaces 132 and 133. Further, this glass 130 and the encapsulant 140 enables the window 121 or the photo sensing surface 111 to be isolated from an outside, thereby preventing outside impurities from permeating.

Next, FIG. 8F shows the aforementioned operation 6. In operation 6, the substrate 120 is bent so as to pass one side surface 115 of the image sensor die 110 and extend over the non-photo sensing surface 114. Then, the adhesive 124 is interposed between the non-photo sensing surface 114 of the image sensor die 110 and the substrate 120, so that the non-photo sensing surface 114 is mechanically attached to the substrate 120. Herein, the curved portion 126 is formed at one side of the substrate 120 so as to prevent the electrically conductive patterns 123 from being broken. Further, the side surface 128 formed at another side of the substrate 120 does not protrude farther than the side surface 132 of the glass 130, so that the size of the semiconductor package becomes nearly equal to that of the image sensor die 110.

Next, FIG. 8G shows the aforementioned operation 7. In operation 7, flux is dotted into the holes 125 of the substrate 120, and spherical solder balls 150 are located on the flux. Then, the substrate 120 with the solder balls and the flux is passed through a furnace at a high temperature, so that the solder balls 150 are electrically connected to the electrically conductive patterns 123 of the substrate 120. Then, the semiconductor package according to the present invention is completed.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

1. A semiconductor package comprising:
an image sensor die comprising:
a photo sensing surface, the photo sensing surface converting lights incident from an outside into electrical signals;
bond pads formed around the photo sensing surface;
first conductive bumps formed at the bond pads;
a non-photo sensing surface opposite to the photo sensing surface; and
side surfaces, each of the side surfaces formed between the photo sensing surface and the non-photo sensing surface;
a substrate comprising:
an insulative layer comprising a window formed at an area corresponding to the photo sensing surface of the image sensor die, the insulative layer attached to the non-photo sensing surface of the image sensor die by a first adhesive;
electrically conductive patterns formed at the insulative layer and connected to the first conductive bumps, the electrically conductive patterns extending over one of the side surfaces and the non-photo sensing surface of the image sensor die; and
first holes formed at the insulative layer corresponding to the non-photo sensing surface so that the electrically conductive patterns are opened downward; and
a glass attached to the insulative layer of the substrate by a second adhesive to cover the window.

2. The semiconductor package as claimed in claim 1, wherein solder balls are attached to the first holes of the insulative layer to be connected to the electrically conductive patterns.

3. The semiconductor package as claimed in claim 1, wherein the first conductive bumps are encapsulated by an encapsulant.

4. The semiconductor package as claimed in claim 3, wherein the encapsulant is located outside of the photo sensing surface of the image sensor die and between the image sensor die and the substrate.

5. The semiconductor package as claimed in claim 3, wherein the encapsulant is made from under fill, glob top, or coating material.

6. The semiconductor package as claimed in claim 1, wherein a first curved portion having a curvature is further formed at an area corresponding to the one of the side surfaces of the image sensor die.

7. The semiconductor package as claimed in claim 1, wherein second conductive bumps are inserted into the first holes of the substrate and are connected to a first memory die.

8. The semiconductor package as claimed in claim 7, wherein the substrate is attached to the first memory die by a third adhesive.

9. The semiconductor package as claimed in claim 8, wherein the substrate has second holes formed at the insulative layer in an area corresponding to the first memory die so that the electrically conductive patterns are exposed downward, and solder balls are attached to the second holes so that the solder balls are electrically connected to the electrically conductive patterns.

10. The semiconductor package as claimed in claim 1, wherein a lower surface of the substrate corresponding to the non-photo sensing surface of the image sensor die is attached to a first memory die by a third adhesive.

11. The semiconductor package as claimed in claim 10, wherein the first memory die is connected to the electrically conductive patterns by second conductive bumps.

12. The semiconductor package as claimed in claim 11, wherein the substrate has second holes formed in the insulative layer in an area corresponding to the first memory die so that the electrically conductive patterns are exposed downward, and solder balls are attached to the second holes so that the solder balls are electrically connected to the electrically conductive patterns.

13. A semiconductor package comprising:
an image sensor die comprising:
a photo sensing surface, the photo sensing surface converting lights incident from an outside into electrical signals;
bond pads formed around the photo sensing surface;
first conductive bumps formed at the bond pads;
a non-photo sensing surface opposite to the photo sensing surface; and
side surfaces, each of the side surfaces formed between the photo sensing surface and the non-photo
sensing surface;
a substrate comprising:
an insulative layer comprising a window formed at an area corresponding to the photo sensing surface of the image sensor die;
electrically conductive patterns formed at the insulative layer and connected to the first conductive bumps, the electrically conductive patterns extending over one of the side surfaces and the non-photo sensing surface of the image sensor die; and
first holes formed at the insulative layer corresponding to the non-photo sensing surface so that the electrically conductive patterns are opened downward;
a glass attached to the insulative layer of the substrate by an adhesive to cover the window;
a first memory die electrically connected to the electrically conductive patterns; and
a second memory die electrically connected to the electrically conductive patterns.

14. The semiconductor package as claimed in claim 13, wherein the non-photo sensing surface of the image sensor die is attached to the second memory die by an adhesive.

15. The semiconductor package as claimed in claim 13, wherein an upper surface of the first memory die is attached to a third memory die by an adhesive, and the third memory die is electrically connected to the electrically conductive patterns.

16-21. (canceled)

22. The semiconductor package as claimed in claim 24 further comprising solder balls electrically connected to the electrically conductive patterns.

23. The semiconductor package as claimed in claim 24 wherein solder balls are electrically connected to the electrically conductive patterns through holes in the insulative layer.

24. A semiconductor package comprising:
an image sensor die comprising:
a photo sensing surface; and
bond pads formed around the photo sensing surface;
a substrate comprising:
an insulative layer extending over at least one side surface of the image sensor die, the photo sensing surface being exposed through a window of the insulative layer; and
electrically conductive patterns electrically connected to the bond pads, the electrically conductive patterns extending over the at least one side surface of the image sensor die;
a glass attached to the insulative layer of the substrate to cover the window; and
a memory die attached to a non-photo sensing surface of the image sensor die.

25. The semiconductor package as claimed in claim 24 further comprising conductive bumps interposed between the memory die and the electrically conductive patterns.
